(19) United States
(12) Patent Application Publication
(10) Pub. No.: US 2013/0207266 A1
(43) Pub. Date: Aug. 15, 2013

(54) Copper Interconnect for III-V Compound Semiconductor Devices

(71) Applicants: Chang-Hwang Hua, (US); Wen Chu, (US)

(72) Inventors: Chang-Hwang Hua, (US); Wen Chu, (US)

(21) Appl. No.: 13/533,303

(22) Filed: Jun. 26, 2012

(30) Foreign Application Priority Data
Feb. 10, 2012 (TW) 101104376

(51) Int. Cl. H01L 23/535

(52) U.S. Cl. 257/745; 257/E23.168

(57) ABSTRACT

The present invention provides a copper interconnect for III-V compound semiconductor devices, which comprises a metal contact layer and a copper-containing metal layer, in which the metal contact layer is formed of a material selected from a group consisting of Ti/Pd/Cu, Ti/NiV/Cu, TiW/TiWN/TiW/Cu, TiW/TiWN/TiW/Au, TiW/Cu, and TiW/Au, and the copper-containing metal layer comprises a copper layer. The copper-containing metal layer further includes a metal protection layer covering on the copper layer to prevent the copper layer from oxidation. The metal protection layer is formed of Ni/Au, Ni/Pd/Au, NiV/Au, or solder.

### FIELD OF THE INVENTION

The present invention relates to a copper interconnect for semiconductor devices. In particular to a copper interconnect for III-V compound semiconductor devices.

### BACKGROUND OF THE INVENTION

Due to the high stability of gold, conventional metal interconnects in the front-end manufacturing process of compound semiconductor integrated circuits are usually made of gold-containing metals. However, the high cost of gold has become one of the bottlenecks of reducing the manufacturing cost in compound semiconductor industry. In addition, integrated circuits with higher integration and higher efficiency demands metals with lower resistivity and higher thermal conductivity for interconnects. As shown in table 1, comparing with gold, copper is an excellent alternative due not only to its lower resistivity, but also to its higher thermal conductivity for improving the heat dissipation efficiency and the device thermal stability. Most importantly, copper is much cheaper than gold. Therefore, replacing gold by copper is of great benefit in the manufacturing process of compound semiconductor integrated circuits.

TABLE 1

| | | Thermal | | |
|---|---|---|---|---|
| | Resistivity | conductivity | Melting point | Prices |
| Material | (μ-Ωcm) | (cal/cm sec ° C.) | (° C.) | (USD/Oz) |
| Cu | 1.69 | 0.94 | 1083 | Neglect |
| Au | 2.4 | 0.7 | 1063 | ~1783 |

However, the main obstacle to implementing copper processes arises from the copper diffusion problem. In semiconductor integrated circuits, copper atoms can diffuse easily into semiconductors. If the diffused copper atoms reach the active regions of the underneath devices, the device performance will be degraded or even damaged. Therefore, to replace gold by copper in the manufacturing process of semiconductor integrated circuits, searching a suitable material as a barrier layer to prevent copper diffusions is of primary importance. In silicon-based semiconductor integrated circuits, there already exist various technologies and inventions for copper process. However, these technologies cannot be applied directly to the compound semiconductor technology. The present invention provides a copper interconnect specific for compound semiconductor devices, so that the costly gold can be replaced by copper in the front-end manufacturing process.

### SUMMARY OF THE INVENTION

The main object of the present invention is to provide a copper interconnect for III-V compound semiconductor devices, which replaces the most commonly used gold interconnects by copper interconnects in the front-end manufacturing process, so that the resistance of the integrated circuit can be lowered, the heat dissipation efficiency can be improved, and the manufacturing cost can be reduced.

To reach the objects stated above, the present invention provides a copper interconnect for III-V compound semiconductor devices, which comprises a metal contact layer and a copper-containing metal layer. The metal contact layer is formed of a material selected from a group consisting of Ti/Pd/Cu, Ti/NiV/Cu, TiW/TiWN/TiW/Cu, TiW/TiWN/TiW/Au, TiW/Cu, and TiW/Au. The copper-containing metal layer comprises a copper layer. The copper-containing metal layer can further includes a metal protection layer covering on the copper layer for preventing said copper layer from oxidation. The metal protection layer is formed of Ni/Au, Ni/Pd/Au, NiV/Au, or solder.

In implementations, the copper layer and the metal protection layer are formed by electroplating or sputtering.

In implementations, the metal contact layer is formed by sputtering or evaporation.

In implementations, the metal contact layer, the copper-containing metal layer and the metal protection layer can all be formed by evaporation or sputtering when the metal contact layer is formed of Ti/Pd/Cu or Ti/NiV/Cu, so that the manufacturing process can be simplified.

For further understanding the characteristics and effects of the present invention, some preferred embodiments referred to drawings are in detail described as follows.

### BRIEF DESCRIPTION OF DRAWINGS

FIG. 1 is a schematic showing the cross-sectional view of a copper interconnect for III-V compound semiconductor devices provided by the present invention.

FIG. 2 is a schematic showing the cross-sectional view of an embodiment of copper interconnects for III-V compound semiconductor devices provided by the present invention.

### DETAILED DESCRIPTIONS OF PREFERRED EMBODIMENTS

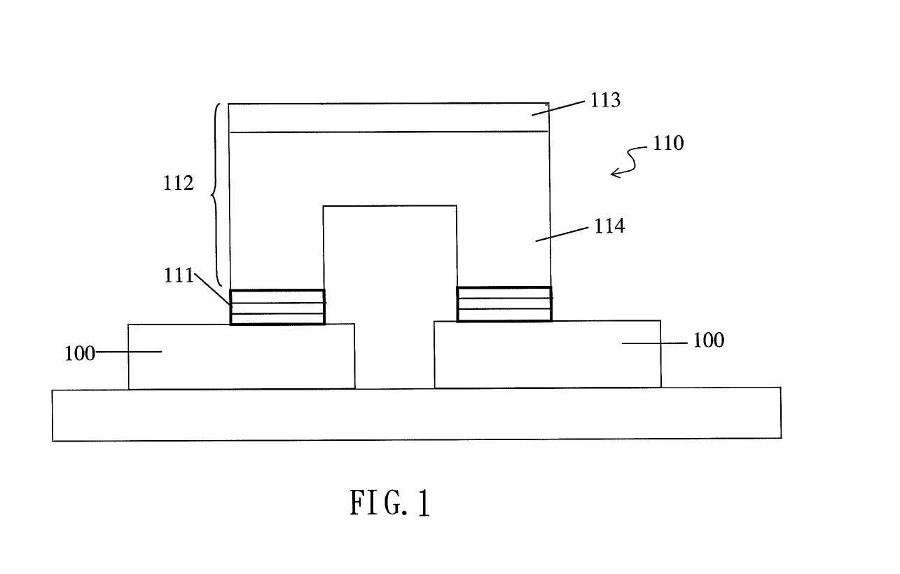

FIG. 1 is a schematic showing the cross-sectional view of III-V compound semiconductor devices 100 with a copper interconnect 110 thereon provided by the present invention. The copper interconnect 110 includes a metal contact layer 111 and a copper-containing metal layer 112. The copper-containing metal layer comprises a copper layer 114. The metal contact layer 111 is disposed under the copper-containing metal layer 112, which further includes an adhesion layer for adhering to the underneath semiconductor material, a barrier layer for avoiding the diffusion of copper atoms, and a metal seed layer for enhancing the adhesion to the copper layer 114 thereon. The metal contact layer 111 is formed of a material selected from a group consisting of Ti/Pd/Cu, Ti/NiV/Cu, TiW/TiWN/TiW/Cu, TiW/TiWN/TiW/Au, TiW/Cu, and TiW/Au, in which the Ti layer is used for adhering to the semiconductor material; the Pd, NiV, and TiWN layers are used as a diffusion barrier for copper atoms; the TiW layer can be used for acting as both a adhesion layer and a diffusion barrier layer; the thin Au and Cu layers are used as seed layers for enhancing the adhesion to the copper-containing metal layer 112. The copper-containing metal layer 112 further includes a metal protection layer 113 covering the copper layer 114 for preventing the copper from oxidation. The metal protection layer 113 is formed preferably of Ni/Au, Ni/Pd/Au, NiV/Au, or solder.

The copper interconnect 110 is disposed in compound semiconductor devices by the following manufacturing steps: first, the device is covered with a passivation layer 120. Then, the metal contact layer 111 is deposited onto the passivation layer 120 by evaporation or sputtering, in which the thickness of the Ti layer of the metal contact layer 111 is preferably between 0.003 to 0.1 μm; the thickness of the Pd layer is preferably between 0.03 to 1.0 μm; the thickness of the NiV layer is preferably between 0.03 to 1.0 μm; the thickness of the TiW layer is preferably between 0.01 to 0.2 μm; the thickness of the TiWN layer is preferably between 0.01 to 0.2 μm; the thickness of the Cu layer of the seed layer in the metal contact layer 111 is preferably between 0.05 to 1.0 μm. The copper-containing metal layer 112 is then disposed on the metal contact layer 111 following from standard photolithography processes. The copper layer and the Ni/Au layer, the Ni/Pd/Au layer, the NiV/Au layer, or the solder layer of the metal protection layer are then deposited sequentially by electroplating or sputtering, in which the thickness of the copper layer is preferably between 0.1 to 10 μm; the thickness of the Ni layer of the metal protection layer is preferably between 0.1 to 3.0 μm; the thickness of the Pd layer of the metal protection layer is preferably between 0.03 to 1.0 μm; the thickness of the Au layer of the metal protection layer is preferably between 0.08 to 1.0 μm; the thickness of the solder layer of the metal protection layer is preferably between 0.1 to 3.0 μm. After removing unnecessary metal layers and mask layers by standard lift-off processes, the copper-containing metal layer 112 is covered with a passivation layer for protecting and isolating the copper-containing metal layer 112. A copper interconnect is completed up to this step. It is worth to mention that, when the metal contact layer is formed of Ti/Pd/Cu or Ti/NiV/Cu, the metal contact layer, the copper layer, and the metal protection layer can all be deposited by evaporation, thereby simplifying the manufacturing processes considerably.

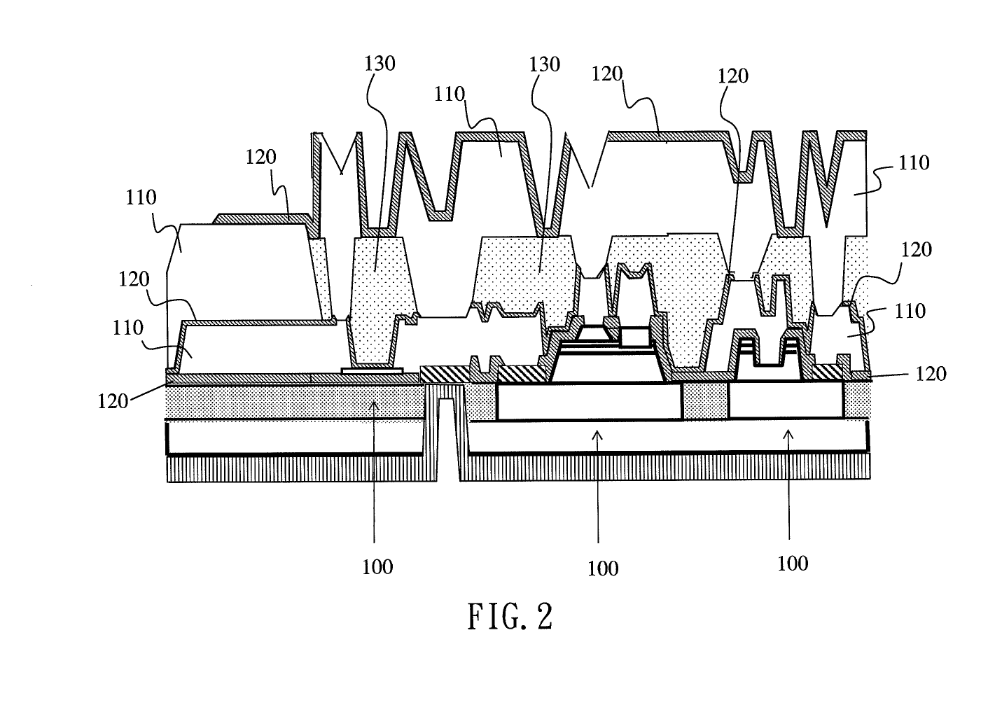

FIG. 2 is a schematic showing an embodiment of copper interconnects for III-V compound semiconductor devices provided by the present invention, which includes at least one III-V compound semiconductor device 100, one copper interconnects 110, and one passivation layer 120. The III-V compound semiconductor device is made of GaAs, InP, or GaN III-V compound semiconductor material. The III-V compound semiconductor device can be a HBT, a HEMT, a diode or other III-V compound semiconductor devices. Before depositing a copper interconnect, semiconductor devices are first covered with a passivation layer 120 to protect the compound semiconductor devices. The passivation layer 120 is made preferably of SiNₓ. The copper interconnect 110 can be used for connecting a semiconductor device either to external contact pads or to other devices. Depending on the request, multiple layers of copper interconnects can be formed on semiconductor devices for multipurpose. Each of the multiple layers of copper interconnects is covered with a passivation layer 120 for both protection and isolation from other copper interconnect layers. The passivation layer 120 is made preferably of SiNₓ. Before covering the copper interconnect with another copper interconnect, the copper interconnect can be covered with a dielectric layer 130 first to reduce the capacitance between the two copper interconnect layers. The dielectric layer 130 is made of a dielectric material of good insulation property, such as polyimide. The topmost copper interconnect layer is finally covered with a passivation layer 120 for protecting the whole compound semiconductor integrated circuit.

To sum up, the present invention can indeed get its anticipatory object by providing a copper interconnect for III-V compound semiconductor devices, in which gold is replaced by copper in the front-end manufacturing process, so that the resistance of the integrated circuit can be lowered, the heat dissipation efficiency can be improved, and the manufacturing cost can be reduced.

The description referred to the drawings stated above is only for the preferred embodiments of the present invention. Many equivalent local variations and modifications can still be made by those skilled at the field related with the present invention and do not depart from the spirits of the present invention, so they should be regarded to fall into the scope defined by the appended claims.

1. A copper interconnect for III-V compound semiconductor devices, comprising a metal contact layer and a copper-containing metal layer, wherein said metal contact layer is formed of a material selected from a group consisting of Ti/Pd/Cu, Ti/NiV/Cu, TiW/TiWN/TiW/Cu, TiW/TiWN/TiW/Au, TiW/Cu, and TiW/Au; and said copper-containing metal layer comprises a copper layer.

2. The copper interconnect for III-V compound semiconductor devices according to claim 1, wherein said metal contact layer is formed by sputtering or evaporation.

3. The copper interconnect for III-V compound semiconductor devices according to claim 1, wherein said copper layer is formed by electroplating.

4. The copper interconnect for III-V compound semiconductor devices according to claim 1, wherein said copper-containing metal layer further includes a metal protection layer covering on said copper layer for preventing said copper layer from oxidation.

5. The copper interconnect for III-V compound semiconductor devices according to claim 4, wherein said metal protection layer is formed of Ni/Au, Ni/Pd/Au, NiV/Au, or solder.

6. The copper interconnect for III-V compound semiconductor devices according to claim 5, wherein said metal protection layer is formed by electroplating or sputtering.

7. The copper interconnect for III-V compound semiconductor devices according to claim 5, wherein the thickness of said Ni layer of said metal protection layer is between 0.1 and 3 μm.

8. The copper interconnect for III-V compound semiconductor devices according to claim 5, wherein the thickness of said NiV layer of said metal protection layer is between 0.1 and 3 μm.

9. The copper interconnect for III-V compound semiconductor devices according to claim 5, wherein the thickness of said Pd layer of said metal protection layer is between 0.03 and 1.0 μm.

10. The copper interconnect for III-V compound semiconductor devices according to claim 5, wherein the thickness of said Au layer of said metal protection layer is between 0.08 and 1.0 μm.

11. The copper interconnect for III-V compound semiconductor devices according to claim 5, wherein the thickness of said solder layer of said metal protection layer is between 0.1 and 3.0 μm.

12. The copper interconnect for III-V compound semiconductor devices according to claim 1, wherein said metal contact layer and said copper layer are formed by evaporation when metal contact layer is formed of Ti/Pd/Cu or Ti/NiV/Cu.

13. The copper interconnect for III-V compound semiconductor devices according to claim 12, wherein said copper-containing metal layer further includes a metal protection layer covering on said copper layer for preventing said copper layer from oxidation.

14. The copper interconnect for III-V compound semiconductor devices according to claim 13, wherein said metal protection layer is formed of Ni/Au, Ni/Pd/Au, NiV/Au, or solder.

15. The copper interconnect for III-V compound semiconductor devices according to claim 13, wherein said metal protection layer is formed by evaporation or sputtering.

16. The copper interconnect for III-V compound semiconductor devices according to claim 14, wherein the thickness of said Ni layer of said metal protection layer is between 0.1 and 3 μm.

17. The copper interconnect for III-V compound semiconductor devices according to claim 14, wherein the thickness of said NiV layer of said metal protection layer is between 0.1 and 3 μm.

18. The copper interconnect for III-V compound semiconductor devices according to claim 14, wherein the thickness of said Pd layer of said metal protection layer is between 0.03 and 1.0 μm.

19. The copper interconnect for III-V compound semiconductor devices according to claim 14, wherein the thickness of said Au layer of said metal protection layer is between 0.08 and 1.0 μm.

20. The copper interconnect for III-V compound semiconductor devices according to claim 14, wherein the thickness of said solder layer of said metal protection layer is between 0.1 and 3.0 μm.

21. The copper interconnect for III-V compound semiconductor devices according to claim 1, wherein the thickness of said copper layer of said copper-containing metal layer is between 0.1 and 10.0 μm.

22. The copper interconnect for III-V compound semiconductor devices according to claim 1, wherein the thickness of said Ti layer of said metal contact layer is between 0.003 and 0.1 μm.

23. The copper interconnect for III-V compound semiconductor devices according to claim 1, wherein the thickness of said Pd layer of said metal contact layer is between 0.03 and 1.0 μm.

24. The copper interconnect for III-V compound semiconductor devices according to claim 1, wherein the thickness of said NiV layer of said metal contact layer is between 0.03 and 1.0 μm.

25. The copper interconnect for III-V compound semiconductor devices according to claim 1, wherein the thickness of said Cu layer of said metal contact layer is between 0.05 and 1 μm.

26. The copper interconnect for III-V compound semiconductor devices according to claim 1, wherein the thickness of said TiW layer of said metal contact layer is between 0.01 and 0.2 μm.

27. The copper interconnect for III-V compound semiconductor devices according to claim 1, wherein the thickness of said TiWN layer of said metal contact layer is between 0.01 and 0.2 μm.

28. The copper interconnect for III-V compound semiconductor devices according to claim 1, wherein said III-V compound semiconductor devices are HBT, HFET, or diodes.

29. The copper interconnect for III-V compound semiconductor devices according to claim 1, wherein said III-V compound semiconductor devices are made of GaAs, InP, or GaN.

30. The copper interconnect for III-V compound semiconductor devices according to claim 1, wherein a passivation layer is attached below said metal contact layer for preventing the diffusion of the material in said copper interconnect into said III-V compound semiconductor devices and protecting the insulation between said copper interconnect and said III-V compound semiconductor devices.

31. The copper interconnect for III-V compound semiconductor devices according to claim 30, wherein said passivation layer is made of SiNₓ.

32. The copper interconnect for III-V compound semiconductor devices according to claim 1, wherein a passivation layer covers on said copper-containing metal layer for protecting the insulation between said copper interconnect and structure above said copper interconnect.

33. The copper interconnect for III-V compound semiconductor devices according to claim 32, wherein said passivation layer is made of SiNₓ
